(19) United States
(12) Patent Application Publication
(10) Pub. No.: US 2002/0000922 A1
(43) Pub. Date: Jan. 3, 2002

(54) Portable information terminal allowing inputting operation with one hand

(76) Inventors: Hajime Hosaka, Kanagawa (JP); Kosuke Komatsu, Kanagawa (JP)

Correspondence Address: Bell, Boyd & Lloyd LLC, P.O. Box 1135, Chicago, IL, 60690, US

(21) Appl. No.: 09/816,613

(22) Filed: Mar. 23, 2001

(30) Foreign Application Priority Data
Mar. 23, 2000 (JP) P2000-081927

(51) Int. Cl. H03K 17/94; B41J 5/28

(52) U.S. Cl. 341/22; 341/28; 400/488; 400/489; 400/490

(57) ABSTRACT

A superior portable information terminal of the palm size having a keyboard unit wherein the portable information terminal includes a polyhedral structure having a number of component faces including a first component face which accommodates a display screen and a second component face provided adjacent the first component face and having an inputting key set including a number of key tops arranged in a zigzag pattern. Each of the key tops has a rib-like projection formed along a peripheral edge thereof. In an operation condition wherein a user holds the portable information terminal with one hand and observes the display screen, the user can perform key inputting operation using the fingertips of the hand with which the body of the apparatus is held. Further, the user can search for the location of any key through the sense of touch on the rib-like projection or projections obtained from a fingertip.

### BACKGROUND OF THE INVENTION

1. Field of the Invention

This present invention relates to a portable information terminal which is small in size, light in weight and superior in portability.

2. Description of the Prior Art

As technical innovations in recent years proceed, various information processing products, from expensive apparatus of high functions for enterprises and research organizations and particular works to apparatus for general consumers which are comparatively less expensive and can be operated simply and readily, have been developed and placed on the market and, thus, spread widely. Particularly recently, as advancement of wiring techniques for semiconductor devices and other manufacturing techniques proceeds rapidly, the tendency of miniaturization and reduction in weight of information terminals is increasing. As portable information processing apparatus, not only notebook PCs (personal computers) of the A4 size or the B5 size, but also PDAs (Personal Digital Assistants) of the palm size called “palm-top” PDAs and multi-function portable terminals equipped with various functions such as a portable telephone function and an Internet accessing function are increasing.

With regard to portable terminals, consumers do not have a fixed product image as yet, and a standard design or a standard form factor in the industry is not established either, except that they have a substantially rectangular parallelepiped housing. However, since a portable terminal has a footprint only of the palm size, it is almost impossible to equip it with a full keyboard of the “QWERTY” arrangement like a conventional notebook PC. Further, it is considered that at least one face of the footprint should be allocated so as to arrange a display section thereon. Accordingly, operation elements such as keys and buttons must be arranged at the remaining location of the housing, and user inputting is limited significantly.

It is demanded that a user operation section of a portable terminal of the type described above satisfy, for example, the following requirements:

(1) It does not interfere with the display section;

(2) The user can operate it with one hand; and

(3) The user can operate it while observing the display section.

In the social conditions wherein popularization of portable information terminals such as portable telephone sets with an electronic mail function has proceeded and is proceeding, it is estimated that a demand for such information inputting irrespective of the time and the place that a writing is written at any time and at any place increases progressively.

In order to have information inputting which is performed irrespective of the time and the place, preferably the portable terminal can be operated with only one hand. This is because such a working environment is envisioned that, for example, the user performs a text inputting operation using one hand on a train in a posture wherein the user holds a strap with the other hand, or the user performs a text inputting operation with one hand while holding baggage with the other hand.

However, a portable information terminal which is provided with a display apparatus and allows information inputting by operation with only one hand is not available as of yet. When it is tried to hold a body of a conventional portable information terminal with a display function with only one hand and operate keys on the body, if the portable information terminal is inadvertently operated improperly during key inputting operation, then the terminal may possibly drop from the palm of the user. Further, while generally the burden of key inputting is distributed to a number of fingers, a portable terminal which facilitates complicated inputting operation such as simultaneous depression of adjacent keys depending only upon the sense of touch at a fingertip is also not available as yet.

Among conventional portable telephone sets, a product which allows document inputting using numeral keys and several other auxiliary keys is available. In this instance, in order to operate the telephone set with only one hand, the keys must be operated only with the thumb while the telephone set body is grasped with the four fingers from the forefinger on down so that it may not be let off.

Consequently, the burden is concentrated only upon the single thumb, which results in extreme exhaustion of the thumb. Further, it is not possible to perform key operations using different fingers alternately to raise the inputting rate either. Further, since the number of keys is small, a very great number of key strokes are required in order to input ordinary alphanumeric characters or kana and kanji characters, and a long time is required for inputting operation. Further, since the number of input characters greater than the number of keys/buttons is provided by combinations of two or more key inputs, the inputting operation is also complicated.

Furthermore, in order to operate the telephone set with the telephone set body of an elongated configuration grasped with a hand, it must be used in a state wherein the wrist is bent in an unnatural form. Besides, the top face of the telephone set must be shared by a display panel and a keyboard. Consequently, the screen size of the display panel is limited, and it cannot be avoided to observe part of an inputted sentence in the very limited display area of the display panel. Further, since the key size is limited inevitably, the portable telephone set is poor in operability.

### SUMMARY OF THE INVENTION

It is, therefore, an object of the present invention to provide a superior portable information terminal of the palm size which is small in size, light in weight and superior in portability and allows operation thereof with only one hand.

It is another object of the present invention to provide a superior portable information terminal of the palm size which has a substantially rectangular parallelepiped form factor and includes a display section disposed on at least one of the faces of the form factor.

It is a further object of the present invention to provide a superior portable information terminal of the palm size which includes a keyboard unit which can be operated fully with only the fingertips of one hand.

In order to attain the objects described above, according to an aspect of the present invention, there is provided a portable information terminal which allows an inputting operation with one hand, including a polyhedral structure having a number of component faces including a first component face which accommodates a display screen and a second component face provided adjacent the first component face for accepting a number of different user inputs.

In the portable information terminal, four or more input keys may be arranged in a zigzag pattern on the second component face. In this instance, each of the input keys may have a linear or rib-like projection formed along a peripheral edge of the top face thereof. A user who operates the keys can confirm the location of a key or the positional relationship between keys only through the sense of touch of a fingertip on the rib-like projection or projections without depending upon the sense of sight.

As an alternative, each of the input keys may have a projection formed at a substantially middle portion of the top face thereof. Further, the projections of adjacent ones of the input keys may be continuous to each other. In this instance, a positional relationship between keys can be searched out readily based only on the sense of touch at a fingertip.

Four or more input keys which can be operated with four fingers of a hand from the forefinger on down may be arranged in a zigzag pattern on the second component face. In this instance, the polyhedral structure may further have a third component face with which the thumb of the hand can contact such that the polyhedral structure can be supported at a portion of the hand in the proximity of a root of the thumb.

The third component face may have a key or a button disposed thereon for operation using the thumb of the hand. For example, a Shift key, a Ctrl key, a Caps Lock key and/or an operation section, which is allocated for inputting of a coordinate or a direction, may be disposed on the third component face.

The third component face disposed in an opposing relationship to the second component face may have arranged thereon a left hand operation section which can be operated using the thumb of the left hand and a right hand operation section which can be operated using the thumb of the right hand. In such an instance, the portable information terminal can be operated in both of a right hand operation mode and a left hand operation mode. Further, the portable information terminal may change over the allocation of input keys disposed on the second component face in response to a current operation mode of the portable information terminal.

Further, four or more input keys may be arranged in a zigzag pattern in two rows on the second component face. In this instance, a key top of each of the input keys in each of the two rows may be supported for pivotal motion around a fulcrum at an edge portion thereof remote from the other key row. As a result, a portion of the key top near to the other key row can be yieldably moved when depressed. Accordingly, when two or more adjacent keys in the different rows are depressed at a time with a single fingertip, strong force is not required, and therefore, the operability in key inputting is augmented.

Where four or more input keys are arranged in a zigzag pattern on the second component face, all of the key pitches need not be made uniform. The key pitch may be different, for example, between those keys which are operated with the fingertip of a finger having a comparatively great range of movement such as the forefinger and those keys which are operated with the fingertip of another finger having a comparatively small range of movement such as the little finger which is low in muscular strength.

A connection port to an external apparatus and/or a slot for insertion and removal of a medium may be disposed on one of the component faces other than the first and second component faces of the polyhedral structure so that the connection capability, compatibility and expandability with an external apparatus may be provided.

According to another aspect of the present invention, there is provided a portable information terminal which allows an inputting operation with one hand, including a polyhedral structure having a number of component faces including a keyboard face having four or more input keys arranged in a zigzag pattern thereon and operable with four fingers of a hand from the forefinger on down, and a thumb operation face disposed in an opposing relationship to the keyboard face for being contacted with the thumb of the hand.

In the portable information terminal, a rib-like projection may be formed along a peripheral edge of the top face of each of the input keys of the keyboard face. In such an instance, a user who operates the keys can confirm the location of a key or the positional relationship between keys only through the sense of touch of a fingertip on the rib-like projection or projections without depending upon the sense of sight.

As an alternative, a projection may be formed at a substantially middle portion of the top face of each of the input keys of the keyboard face. In this instance, the projections of adjacent ones of the input keys may be continuous to each other. In this instance, a positional relationship between keys can be searched out readily based only on the sense of touch at a fingertip.

The thumb operation face may have arranged thereon a left hand operation section which can be operated using the thumb of the left hand and a right hand operation section which can be operated using the thumb of the right hand. In such an instance, the portable information terminal can be operated in both of a right hand operation mode and a left hand operation mode. Further, the portable information terminal may change over the allocation of input keys disposed on the keyboard face in response to a current operation mode of the portable information terminal.

The four or more input keys may be arranged in a zigzag pattern in two rows on the keyboard face. In such an instance, a key top of each of the input keys in each of the two rows may be supported for pivotal motion around a fulcrum at an edge portion thereof remote from the other key row. In this instance, a portion of the key top near to the other key row can be yieldably moved when depressed. Accordingly, when two or more adjacent keys in the different rows are depressed at a time with a single fingertip, strong force is not required and, therefore, the operability in key inputting is augmented.

Where the four or more input keys are arranged in a zigzag pattern on the keyboard face, all of the key pitches need not be made uniform. The key pitch may be different, for example, between those keys which are operated with the fingertip of a finger having a comparatively great range of movement such as the forefinger and those keys which are operated with the fingertip of another finger having a comparatively small range of movement such as the little finger which is low in muscular strength.

In summary, a portable information terminal according to the present invention includes a polyhedral structure having a number of component faces including a first component face which accommodates a display screen and a second component face provided adjacent the first component face for accepting a number of different user inputs.

An inputting key set including four or more key tops arranged in a zigzag pattern is disposed on the second component face. Further, a rib-like projection indicting a boundary is formed along a peripheral edge of each key top.

Consequently, even in such an operation condition that, for example, the user holds the portable information terminal with one hand and observes the display screen, the user can perform key inputting operation appropriately by using the fingertips of the hand with which the body of the apparatus is held.

Further, the user can search for the location of a key or the positional relationship between keys through the sense of touch of a fingertip on the rib-like projection or projections obtained from a fingertip. Accordingly, the user can operate the input key set composed of four or more key tops while observing the display screen without turning the eyes away from the screen.

The above and other objects, features and advantages of the present invention will become apparent from the following description and the appended claims, taken in conjunction with the accompanying drawings in which like parts or elements denoted by like reference symbols.

### DESCRIPTION OF THE DRAWINGS

FIG. 1 is a view schematically showing an appearance configuration of a portable information terminal to which the present invention is applied;

FIG. 2 is a view, similar to FIG. 1, showing a manner wherein the portable information terminal is operated with the right hand;

FIG. 3 is a view, similar to FIG. 1, showing a manner wherein the portable information terminal is operated with the left hand;

FIG. 4 is a schematic view showing a sectional configuration of keys which can be operated with the medical finger of the right hand together with a manner wherein the keys are viewed from the key operation face side;

FIGS. 5 and 6 are views each illustrating a reactive force which acts upon a fingertip from rib-like projections indicated by slanting lines formed along edges of the top faces of the keys shown in FIG. 4;

FIG. 7 is a schematic view illustrating a manner wherein two keys of a combination are operated simultaneously with a fingertip;

FIG. 8 is a view, similar to FIG. 7, illustrating a manner wherein three keys of a combination are operated simultaneously with a fingertip;

FIG. 9 is a view, similar to FIG. 7, illustrating a manner wherein two keys of another combination are operated simultaneously with a fingertip;

FIG. 10 is a similar view but illustrating a manner wherein two keys of a further combination are operated simultaneously with a fingertip;

FIG. 11 is a view, similar to FIG. 7, illustrating a manner wherein two keys of a still further combination are operated simultaneously with a fingertip;

FIG. 12 is a view, similar to FIG. 7, illustrating a manner wherein a single key is operated with a fingertip;

FIG. 13 is a view, similar to FIG. 7, but illustrating a manner wherein two keys of a yet further combination are operated simultaneously with a fingertip;

FIG. 14 is a view, similar to FIG. 7, illustrating a manner wherein three different keys of another combination are operated with a fingertip;

FIG. 15 is a view, similar to FIG. 7, illustrating a manner wherein three keys of a further combination are operated with a fingertip;

FIGS. 16 to 18 are views schematically showing a configuration of a keyboard of another portable information terminal to which the present invention is applied;

FIGS. 19 to 21 are views schematically showing a configuration of a keyboard of a further portable information terminal to which the present invention is applied; and

FIGS. 22 to 24 are views schematically showing a configuration of a keyboard of a still further portable information terminal to which the present invention is applied.

### DETAILED DESCRIPTION OF THE PREFERRED EMBODIMENTS

Referring first to FIG. 1, there is shown an appearance of a portable information terminal 10 to which the present invention is applied. The portable information terminal 10 may be a portable telephone set, an information processing terminal (PDA: Personal Digital Assistant) of the palm top type, or a multi-function portable terminal in which various functions such as a portable telephone function and an Internet accessing function are incorporated.

A display screen 12 is disposed on the top face of a body of the portable information terminal 10 and an antenna 13 is disposed on the right side face of the body while an input key set 15 including a large number of input keys are disposed on the front face of the body. In FIG. 1, it is shown that a character string “Hello, Everybody” inputted already is displayed on the display screen 12.

The input key set 15 is formed as an aggregate of four or more key tops 15a to 15r as seen in FIG. 1. The key tops 15a to 15r have a substantially pentagonal top face and are arranged in a zigzag pattern in two rows. It is to be noted that the arranged number of keys of the input key set 15 is not particularly limited and the keys may be arranged otherwise in one row or else in three or more rows. The front face of the portable information terminal 10 forms a key operation face (or a keyboard face).

In FIG. 1, portions indicated by slanting lines denote rib-like projections formed along edges of the top faces of the key tops 15a to 15r. Since the rib-like projections are formed such that they extend along the boundaries between adjacent key tops, with a fingertip of the user with which each of the key tops 15a to 15r is operated, the user can discriminate the boundary between the key top and an adjacent key top with the sense of touch on the rib-like projection between the key tops. In other words, the user can confirm the location of a key or the positional relationship between keys only through the sense of touch without depending upon the sense of sight.

A pair of direction inputting elements 16 and 17 of the pressure sensitive type and keys 18a to 18c and keys 19a to 19c are disposed on the back face of the portable information terminal 10. When necessary, rib-like projections may be formed suitably along peripheral edges of the keys 18a to 18c and the keys 19a to 19c on the rear face side.

The direction inputting elements 16 and 17 can be allocated, for example, to a coordinate indication function for moving a cursor (not shown) on the display screen 12. The direction inputting elements 16 and 17 need not be of the pressure-sensitive type but may be formed from a track ball, a track point or a like element.

The keys 18a to 18c and the keys 19a to 19c can be allocated for functions for controlling key inputs such as a Shift key, a Ctrl key and a Caps Lock key.

The portable information terminal 10 may be used as an independent apparatus only of the terminal body, that is, in a stand-alone state, but otherwise may be connected to a personal computer or some other external apparatus so as to provide a cooperative execution environment between a number of apparatus. As a connection interface to such an external apparatus as just mentioned, an i-link, a USB (Universal Serial Bus), and a serial (RS-232C) port may be used. Further, a cable need not be used for connection, but alternatively, such a medium as a memory stick or a PC card may be used to exchange data with an external apparatus or such short distance radio data communication as IrDA (Infrared Data Association) or Bluetooth may be used. A cable connection portion, a card slot and a radio transmission/reception section for the elements mentioned above are preferably disposed on that one of component faces of a structure forming the body of the portable information terminal 10 on which the display screen 12 or the input key set 15 is not disposed (further preferably on a component face, not shown, which does not cause interference with a key inputting operation).

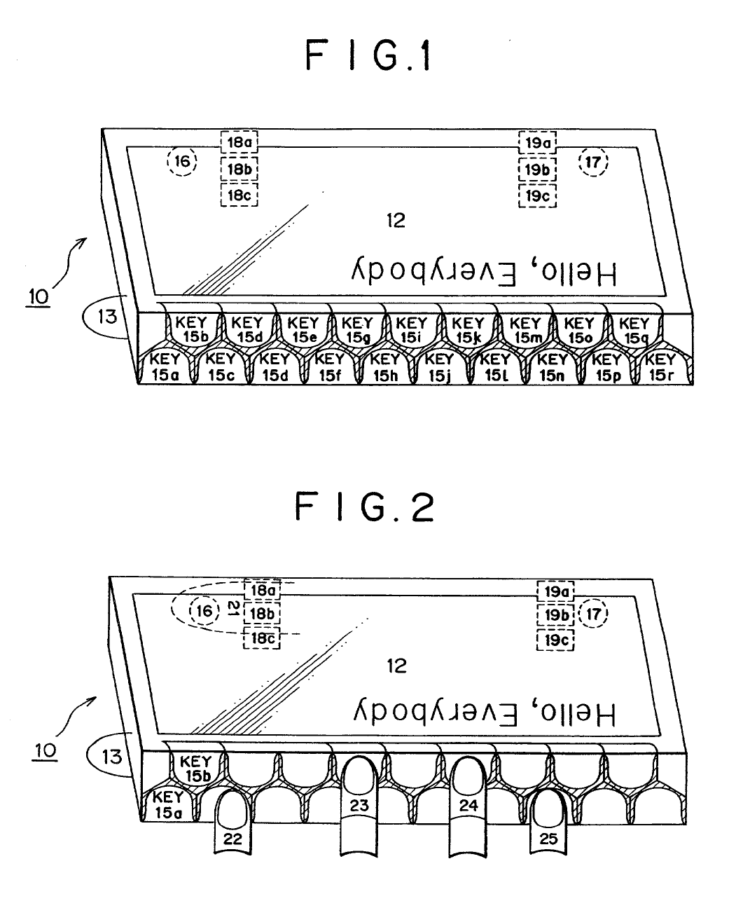

FIG. 2 illustrates a manner wherein the portable information terminal 10 is operated with the right hand. In FIG. 2, it can be seen that the forefinger 22, middle finger 23, medical or ring finger 24 and little finger 25 of the right hand touch on the front face of the body while the thumb 21 of the right hand touches with the rear face of the body such that the portable information terminal 10 can be held in the proximity of the root of the thumb 21.

Where the portable information terminal 10 is held in such a manner as seen in FIG. 2, the fingertips of the four fingers from the forefinger 22 to the little finger 25 can be used to depress the input key set 15 to perform key inputting operations. Further, the thumb 21 can be used to operate the direction inputting element 16 to move the cursor (not shown) on the display screen 12 to an arbitrary position. Also, it is possible to further increase the number of characters which can be inputted through combinations of depressing operations of the keys 18a to 18c using the thumb 21 and depressing operations of the input key set 15 using the four fingers from the forefinger 22 to the little finger 25.

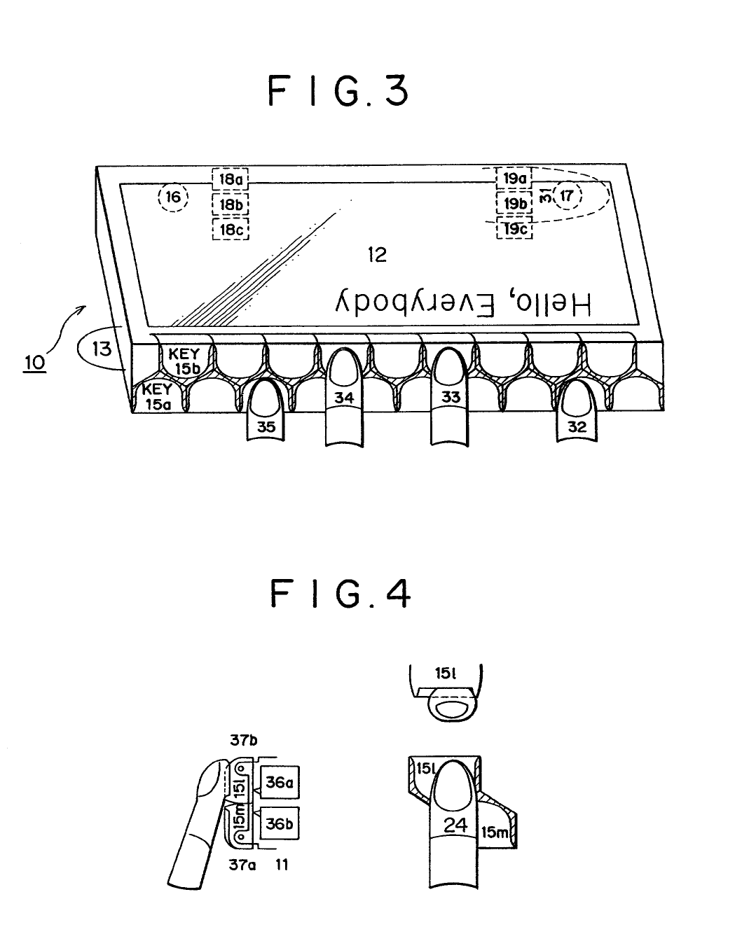

FIG. 3 illustrates a manner wherein the portable information terminal 10 is operated with the left hand. In FIG. 3, it can be seen that the forefinger 32, middle finger 33, medical finger 34 and little finger 35 of the left hand touch on the front face of the body while the thumb 31 of the left hand touches on the rear face of the body such that the body of the portable information terminal 10 can be held in the proximity of the root of the thumb 31.

Where the portable information terminal 10 is held in such a manner as seen in FIG. 3, the four fingers from the forefinger 32 to the little finger 35 can be used to depress the input key set 15 to perform key inputting operations. Further, the thumb 31 can be used to operate the direction inputting element 17 to move the cursor (not shown) on the display screen 12 to an arbitrary position. Also it is possible to further increase the number of characters which can be inputted through combinations of depressing operations of the keys 19a to 19c using the thumb 31 and depressing operations of the input key set 15 with the four fingers from the forefinger 32 to the little finger 35.

In the portable information terminal 10 of the configuration shown in FIGS. 1 to 3, some of the keys of the input key set 15 may otherwise be allocated for the functions of the left and the right buttons of the mouse. For example, where the body of the portable information terminal 10 is held with the right hand in such a manner as seen in FIG. 2, if the key 15a is depressed while the direction inputting element 16 is operated, then it may be operated as the left button of the mouse, and if the key 15e is depressed while the direction inputting element 16 is operated, then it may be operated as the right button of the mouse. In ordinary operation of the mouse, the left button of the mouse is operated with the forefinger 22 and the right button of the mouse is operated with the middle finger 23. Therefore, the operations of the key 15a and the key 15e together with the direction inputting element 16 are common in operation feeling to GUI (Graphical User Interface) operations, which are familiar to the users on an ordinary computer screen and therefore can be accepted widely by users.

Similarly, where the body of the portable information terminal 10 is held with the left hand as shown in FIG. 3, if the key 15r is depressed while the direction inputting element 17 is operated, then it may be operated as the left button of the mouse, and if the key 15m is depressed while the direction inputting element 17 is operated, then it may be operated as the right button of the mouse.

Further, the portable information terminal 10 may have a “right hand mode” which provides an agreeable inputting environment (key assignment and so forth) when it is operated with the right hand and a “left hand mode” which provides an agreeable inputting environment when it is operated with the left hand. For example, when an arbitrary or predetermined one of the keys 19a to 19c is depressed, the portable information terminal 10 may enter the left hand mode, but when an arbitrary or predetermined one of the keys 18a to 18c is depressed, the portable information terminal 10 may return to the right hand mode.

In the right hand mode, the keys 15n to 15r are operated with the little finger 25. On the contrary, in the left hand mode, the keys 15a to 15d are operated with the little finger 35. As can be recognized readily by those skilled in the art, generally the little finger is thin and low in muscular strength when compared with the other fingers, and therefore, it is inferior in operation capacity to, and smaller in range of movement than, the other fingers. Accordingly, the keys 15n to 15r and/or the keys 15a to 15d may be formed with a smaller size than the other keys (not shown) to narrow the object areas of operation of the little finger 25 and/or 35 thereby to reduce the burden to the little finger 25 and/or 35.

Where the keys are formed in various sizes (or in various key pitches) in this manner, two kinds of keys including comparatively large keys and comparatively small keys may be prepared, or key sizes may be gradually decreased toward the little finger 25 and/or 35 side (not shown).

Where the portable information terminal 10 described above with reference to FIGS. 1 to 3 is used, the inputting key set including four or more key tops, that is, the keyboard, can be depressed using the four fingers from the forefinger on down. Accordingly, when compared with an alternative case wherein key inputting operations are performed using only the single thumb as with a conventional portable telephone set, the efficiency in inputting operation is very high and a greater number of characters can be inputted per unit time.

Further, where a conventional portable telephone set or a like apparatus is used, since the operation burden is concentrated only upon the single thumb, it suffers from extremely great exhaustion or fatigue as described hereinabove. In contrast, with the portable information terminal 10 described above, the burden of key inputting operations can be distributed to a number of fingers.

As can be recognized from the comparison between FIGS. 2 and 3, with whichever one of the right and left hands the portable information terminal 10 is grasped, the upward and downward directions of the display screen 12 are not reversed. Accordingly, if the body of the portable information terminal 10 is held with one hand until the hand becomes exhausted, then it can be passed from the hand to the other hand.

FIG. 4 illustrates a sectional configuration of the keys 151 and 15m which can be operated with the medical finger 24 of the right hand together with a manner wherein they are viewed from the key operation face side.

Referring to FIG. 4, the key 151 is supported for pivotal motion by and around a shaft 37b. Preferably, the key 151 is acted upon by a restoring force for biasing the key 151 to a position at which the top face thereof is level with the key operation face.

A micro-switch 36a is disposed on the rear face side of the key 151. The micro-switch 36a is energized when the key 151 is depressed at the top face thereof with a finger of the user and moved downwardly. Since the restoring force acts upon the key 151 to bias the key 151 to the position at which the top face thereof is in level with the key operation face, if the key 151 is released from the depressing operation by the finger of the user, then the key 151 is moved back upwardly and, consequently, the micro-switch 36a is deenergized.

Similarly, the key 15m is supported for pivotal motion by and around a shaft 37a and is acted upon by a restoring force for biasing the key 15m to a position at which the top face thereof is level with the key operation face. A micro-switch 36b is disposed on the rear face side of the key 15m.

The micro-switch 36b is energized when the key 15m is depressed at the top face thereof with a finger of the user and moved downwardly. Since the restoring force acts upon the key 15m to bias the key 15m to the position at which the top face thereof is level with the key operation face, if the key 15m is released from the depressing operation by the finger of the user, then the key 15m is moved back upwardly and, consequently, the micro-switch 36b is deenergized.

If the key 15m and the key 151 are pushed around a middle location therebetween with a fingertip, then they are pivoted around the shafts 37a and 37b and moved down so that both of the micro-switches 36a and 36b can be energized simultaneously, respectively. At this time, since the location depressed by the finger, that is, the point of force, is spaced away from the shafts 37a and 37b, that is, the fulcra of the keys 15m and 151, although the two keys are operated simultaneously, they can be depressed with a comparatively light force. Consequently, the burden to the fingertip is moderated.

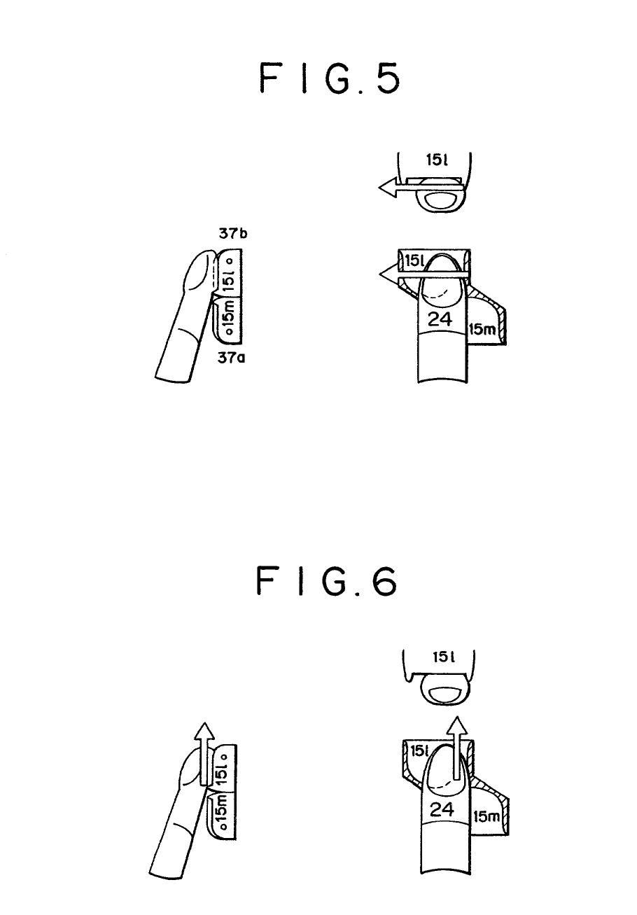

FIGS. 5 and 6 illustrate each a reactive force acting upon a fingertip from a rib-like projection (portion indicated by slanting lines in FIG. 5 and 6) formed along an edge of the top face of each of the keys 151 and 15m.

When the body of the portable information terminal 10 tends to slip down in a lengthwise direction of the body from a palm, a reactive force acts in a direction substantially perpendicular to the direction of the fingertip as indicated by arrow marks in FIG. 5. Similarly, when the body of the portable information terminal 10 tends to slip down in the thicknesswise direction of the body from a palm, a reactive force acts substantially in the direction of the fingertip as indicated by arrow marks in FIG. 6. In other words, due to the rib-like projection on the upper face of each key of the input key set 15, a reactive force in two perpendicular directions acts upon the fingertip.

While only the medical finger 24 is shown as an example in FIGS. 5 and 6, reactive forces in two perpendicular directions act upon any other fingertip similarly. When the portable information terminal 10 is operated with one hand in such a case that the user grips a strap of a train or holds baggage, the portable information terminal 10 is likely to be let off from the hand due to an accidental incident. Since such a reactive force acts upon each of the fingertips, the user can prevent otherwise possible letting off of the portable information terminal 10 appropriately.

Further, even if a finger is moved away from the key operation face so that it may move to a key other than the key at its home position and the force for holding the portable information terminal 10 decreases, the user can prevent letting off of the portable information terminal 10 appropriately due to reactive forces in two directions applied to each of the fingertips.

Where the keys of the input key set 15 are arranged in such a zigzag pattern as seen in FIG. 1, an operation of depressing a number of keys with a single fingertip can be performed readily. Further, since the rib-like projections are formed along the edges of the top faces of the keys 15a to 15r by tracing the sense of touch at a fingertip, how many keys are being depressed at a time can be recognized readily without the user looking at the keys.

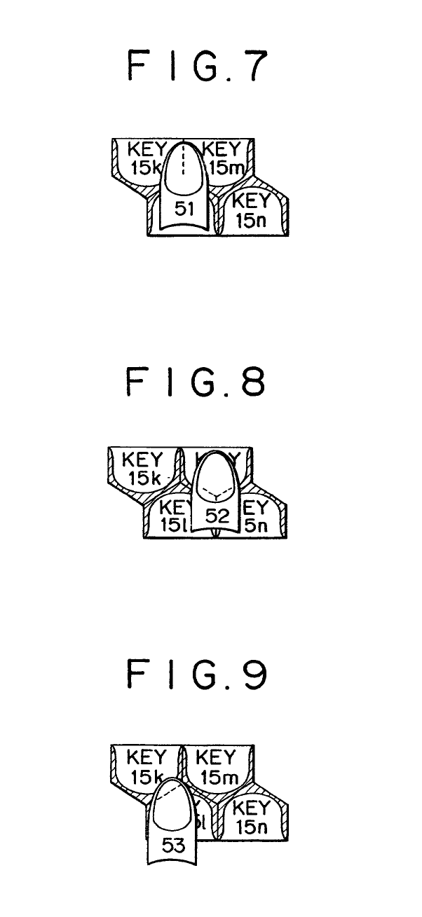

FIGS. 7 to 15 illustrate different manners when the input key set 15 is operated with a fingertip.

FIG. 7 illustrates a manner wherein the two keys 15k and 15m which are adjacent to each other in a horizontal direction are depressed at a time with a fingertip 51. In such an instance, the fingertip 51 can obtain the sense of touch on the boundary (portion indicated by a broken line in FIG. 7) between the keys which is formed from the rib-like projections formed along the peripheral edges of the keys and extends in the vertical direction. Therefore, the user can recognize (with the sense of touch) that two keys are operated simultaneously.

FIG. 8 illustrates a manner wherein only the single key 15m is depressed with a fingertip 52. The condition of FIG. 8 corresponds to a condition wherein the fingertip 51 shown in FIG. 7 is moved rightwardly by a half key pitch on the keyboard. In such an instance, the sense of touch of a substantially V-shape in FIG. 8 (a portion indicated by a broken line in FIG. 8) can be obtained at the fingertip 52 from the rib-like projection along the peripheral edge of the key. Consequently, the user can recognize (with the sense of touch) that only one of those keys in the upper side of the two rows is operated.

FIG. 9 illustrates a manner wherein the two keys 15k and 151 positioned adjacent to each other in an obliquely leftwardly inclined direction are depressed at a time with a fingertip 53. In such an instance, the fingertip 53 can obtain the sense of touch on the boundary (a portion indicated by a broken line in FIG. 9) provided by the rib-like projections formed along the peripheral edges of the keys 15k and 151 and extending in an obliquely rightwardly inclined direction. Consequently, the user can recognize (with the sense of touch) that two keys positioned adjacent to each other in an obliquely leftwardly inclined direction are operated at a time.

FIG. 10 illustrates a manner wherein the two keys 151 and 15m positioned adjacent to each other in an obliquely rightwardly inclined direction are depressed at a time with a fingertip 54. The condition of FIG. 10 corresponds to a condition wherein the fingertip 53 shown in FIG. 9 is moved rightwardly by a half key pitch on the keyboard. In such an instance, the fingertip 54 can feel the sense of touch on the boundary (a portion indicated by a broken line in FIG. 10) provided by the rib-like projections formed along the peripheral edges of the keys 151 and 15m and extending in an obliquely leftwardly inclined direction. Consequently, the user can recognize (with the sense of touch) that two keys positioned adjacent to each other in an obliquely rightwardly inclined direction are operated at a time.

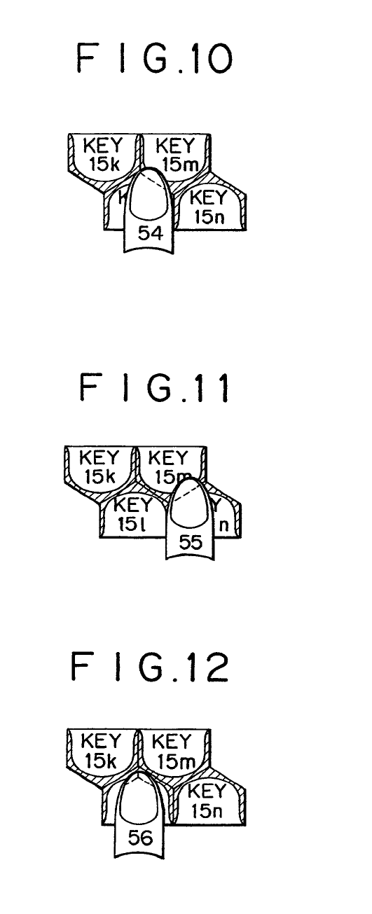

FIG. 11 illustrates a manner wherein the two keys 15m and 15n positioned adjacent to each other in an obliquely leftwardly inclined direction are depressed at a time with a fingertip 55. In such an instance, the fingertip 55 can obtain the sense of touch on the boundary (a portion indicated by a broken line in FIG. 11) provided by the rib-like projections formed along the peripheral edges of the keys 15m and 15n and extending in an obliquely rightwardly inclined direction. Consequently, the user can recognize (with the sense of touch) that two keys positioned adjacent to each other in an obliquely leftwardly inclined direction are operated at a time.

The condition of FIG. 11 corresponds to a condition wherein the fingertip 54 shown in FIG. 10 is moved rightwardly by a half key pitch on the keyboard. When the fingertip 54 slides on the keyboard, it passes the rib-like projection extending in the vertical direction which corresponds to the boundary between the keys 151 and 15n. Therefore, the user can recognize accurately which position the fingertip is moved to, only through the sense of touch.

FIG. 12 illustrates a manner wherein the single key 151 is depressed with a fingertip 56. In such an instance, the fingertip 56 can obtain the sense of touch on a substantially inverted V shape (a portion indicated by a broken line in FIG. 12) provided by the rib-like projection formed along the peripheral edge of the key 151. Consequently, the user can recognize (with the sense of touch) that one of the keys in the lower side of the two rows of keys is depressed.

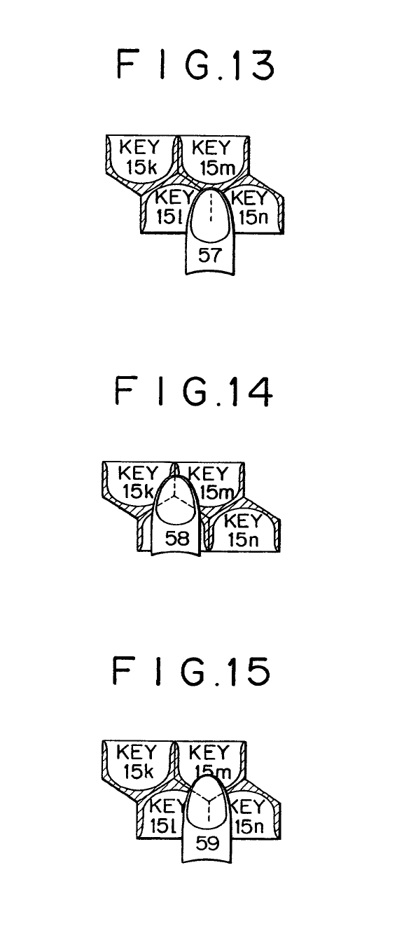

FIG. 13 illustrates a manner wherein the two keys 151 and 15n positioned adjacent to each other in a horizontal direction are depressed at a time with a fingertip 57. The condition of FIG. 13 corresponds to a condition wherein the fingertip 56 shown in FIG. 12 is moved rightwardly by a half key pitch on the keyboard. In such an instance, the fingertip 57 can obtain the sense of touch on the boundary (a portion indicated by a broken line in FIG. 13) provided by the rib-like projections formed along the peripheral edges of the keys 151 and 15n and extending in a vertical direction. Consequently, the user can recognize (with the sense of touch) that two keys are operated at a time.

FIG. 14 illustrates a manner wherein the three keys 15k, 151 and 15m positioned adjacent to each other are depressed at a time with a fingertip 58. The condition of FIG. 14 corresponds to a condition wherein the fingertip 56 shown in FIG. 12 is moved upwardly by a half key pitch on the keyboard. In such an instance, the fingertip 58 can obtain the sense of touch on a substantially inverted Y shape (a portion indicated by a broken line in FIG. 14) provided by the rib-like projections formed along the peripheral edges of the keys 15k, 151 and 15m. Consequently, the user can recognize (with the sense of touch) that three keys positioned adjacent to each other in upward and downward directions are operated at a time.

FIG. 15 illustrates a manner wherein the three keys 151, 15m and 15n positioned adjacent to each other are depressed at a time with a fingertip 59. The condition of FIG. 15 corresponds to a condition wherein the fingertip 57 shown in FIG. 13 is moved upwardly by a half key pitch on the keyboard. In such an instance, the fingertip 59 can obtain the sense of touch on a substantially Y shape (a portion indicated by a broken line in FIG. 15) provided by the rib-like projections formed along the peripheral edges of the keys 151, 15m and 15n. Consequently, the user can recognize (with the sense of touch) that three keys positioned adjacent to each other in upward and downward directions are operated at a time.

In summary, the portable information terminal 10 having such a configuration as described above with reference to FIG. 1 is characterized principally in that, in terms of the design, the input key set 15 is disposed on the side face of the body adjacent to the top face on which the display screen 12 is disposed and that the four or more key tops of the input key set 15 are arranged in a zigzag pattern and a rib-like projection which indicates a boundary is formed along a peripheral edge of each of the key tops.

In particular, since the input key set 15 is disposed on the side face of the body adjacent to the top face on which the display screen 12 is disposed, even in such a working condition that, for example, the user holds the portable information terminal 10 with one hand and observes the display screen 12, the user can perform key inputting operations appropriately by using the fingertips of the hand holding the body of the portable information terminal 10 without depending upon visual observation.

Further, the user can search for a location of each key or a positional relationship between keys by making use of the sense of touch of a finger tip on a rib-like projection. Accordingly, the user can operate the inputting keys composed of four or more key tops without observing them while observing the display screen 12.

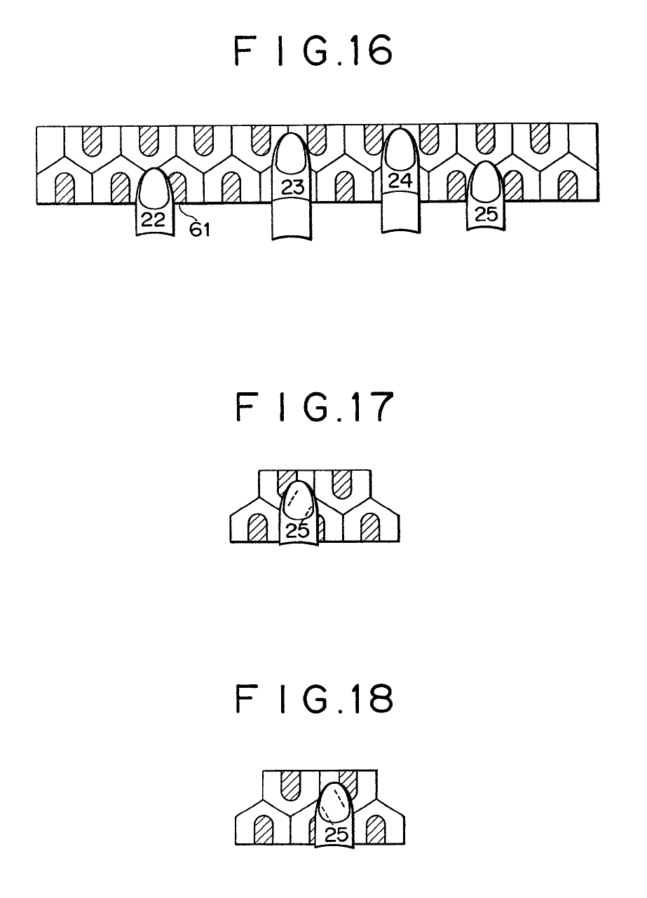

FIGS. 16 to 18 schematically show a configuration of a keyboard of another portable information terminal to which the present invention is applied.

Similarly to the keyboard of the portable information terminal 10 described hereinabove, the keyboard of the portable information terminal according to the present embodiment includes key tops arranged in a zigzag pattern in two rows. Referring to FIGS. 16 to 18, each portion indicated by slanting lines is formed as a moderate projection. While, in the arrangement shown in FIG. 1, a rib-like projection is formed along a peripheral edge of each key top, in the arrangement shown in FIGS. 16 to 18, a projection is provided at a substantially middle portion of each key top.

With the keyboard having such a configuration as described above, when two keys positioned adjacent to each other in an obliquely leftwardly inclined direction are operated at a time with a fingertip, the user can obtain the sense of touch on two lines extending in parallel to each other in an obliquely rightwardly inclined direction along a valley between projections of them as indicated by broken lines in FIG. 17. Consequently, the user can recognize a simultaneous operation of the keys readily.

Similarly, when two keys positioned adjacent to each other in an obliquely rightwardly inclined direction are operated at a time with a fingertip, the user can obtain the sense of touch on two lines extending in parallel to each other in an obliquely rightwardly inclined direction along a valley between projections of them as indicated by broken lines in FIG. 18. Consequently, the user can recognize a simultaneous operation of the keys readily.

FIGS. 19 to 21 schematically show a constriction of a keyboard of a further portable information terminal to which the present invention is applied.

Similarly to the keyboard of the portable information terminal 10 described hereinabove, the keyboard of the portable information terminal according to the present embodiment includes key tops arranged in a zigzag pattern in two rows. Referring to FIGS. 19 to 21, each portion indicated by slanting lines is formed as a moderate projection. While, in the arrangement shown in FIG. 1, a rib-like projection is formed along a peripheral edge of each key top, in the arrangement shown in FIGS. 19 to 21, a projection is provided at a substantially middle portion of each key top, and in the right half portion of the keyboard, the projections of two key tops positioned adjacent to each other in an obliquely rightwardly inclined direction are continuous to each other while, in the left half portion of the keyboard, the projections of two key tops positioned adjacent to each other in an obliquely leftwardly inclined direction are continuous to each other as seen in FIG. 19.

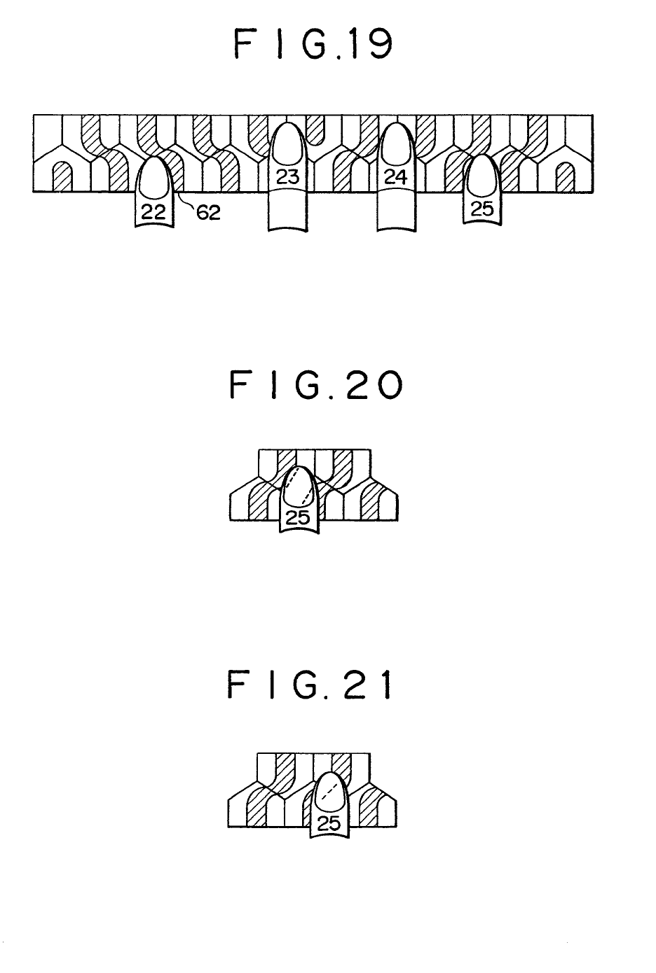

With the keyboard having such a configuration as described above, when two keys positioned adjacent to each other in an obliquely leftwardly inclined direction in the right half of the keyboard in FIG. 19 are operated at a time with a finger, the user can obtain the sense of touch on two lines extending in parallel to each other in an obliquely rightwardly inclined direction along a valley between the projections of the keys as indicated by broken lines in FIG. 20. Consequently, the user can recognize a simultaneous operation of the keys readily.

Similarly, when two keys positioned adjacent to each other in an obliquely rightwardly inclined direction in the right half of the keyboard in FIG. 19 are operated at a time with a finger, the user can obtain the sense of touch on a line extending in an obliquely rightwardly inclined direction along the summits of the projections of them as indicated by broken lines in FIG. 21. Consequently, the user can recognize a simultaneous operation of the keys readily.

Though not particularly shown, when two keys positioned adjacent to each other in an obliquely leftwardly or rightwardly inclined direction in the left half of the keyboard in FIG. 19 are operated at a time with a finger, the user can obtain the sense of a touch on two lines or a line extending in an obliquely leftwardly inclined direction along a valley between the projections or along the summits of the projections of the keys similarly to but symmetrically with those described above. Consequently, the user can recognize a simultaneous operation of the keys readily.

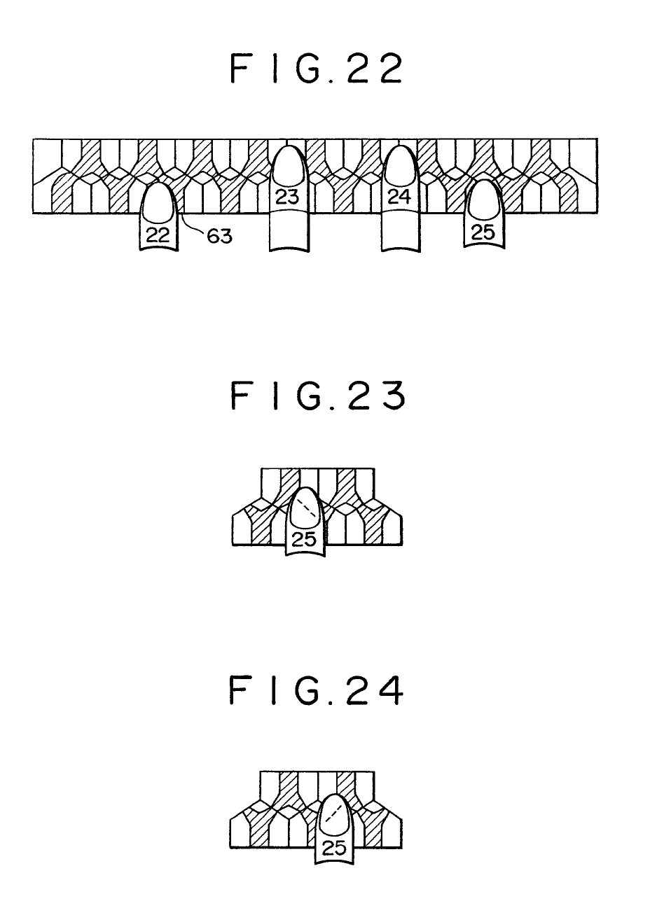

FIGS. 22 to 24 schematically show a configuration of a keyboard of a still further portable information terminal to which the present invention is applied.

Similarly to the keyboard of the portable information terminal 10 described hereinabove, the keyboard of the portable information terminal according to the present embodiment includes key tops arranged in a zigzag pattern in two rows. Referring to FIGS. 22 to 24, each portion indicated by slanting lines is formed as a moderate projection. While, in the arrangement shown in FIG. 1, a rib-like projection is formed along a peripheral edge of each key top, in the arrangement shown in FIGS. 22 to 24, a projection is provided at a substantially middle portion of each key top, and the projections of each key and two key tops positioned adjacent the key in obliquely leftwardly and rightwardly inclined directions are continuous to each other as seen in FIG. 22.

With the keyboard having such a configuration as described above, when two keys positioned adjacent to each other in an obliquely leftwardly inclined direction are operated at a time with a finger, the user can obtain the sense of touch on a line extending in an obliquely leftwardly inclined direction along the summits of the projections of the keys as indicated by a broken line in FIG. 23. Consequently, the user can recognize a simultaneous operation of the keys readily.

Similarly, when two keys positioned adjacent to each other in an obliquely rightwardly inclined direction are operated at a time with a finger, the user can obtain the sense of touch on a line extending in an obliquely rightwardly inclined direction along the summits of the projections of the keys as indicated by a broken line in FIG. 24. Consequently, the user can recognize a simultaneous operation of the keys readily.

As apparent from the foregoing description, according to the present invention, a superior portable information terminal of the palm size which is designed small in size and light in weight and is superior in portability and besides allows operation thereof with only one hand can be provided.

Further, according to the present invention, a superior portable information terminal of the palm size which has a substantially rectangular parallelepiped form factor and includes a display section disposed on at least one of faces of the form factor can be provided.

Furthermore, according to the present invention, a superior portable information terminal of the palm size which includes a keyboard unit which can be operated fully with only fingertips of one hand can be provided.

With the portable information terminal according to the present invention, even in such an operation condition that, for example, the user holds the body of the portable information terminal with one hand and observes the display screen, the user can perform key inputting operation appropriately using the fingertips of the hand with which the body of the apparatus is held without depending upon the sense of sight.

Further, the user can search for the location of a key or the positional relationship between keys through the sense of touch on the rib-like projection or projections obtained from a fingertip. Accordingly, the user can operate the input key set composed of four or more key tops while observing the display screen without turning away the eyes from the display screen.

With the portable information terminal according to the present invention, as described hereinabove with reference to FIGS. 1 to 3, the inputting key set including four or more key tops, that is, the keyboard, can be depressed using the four fingers from the forefinger on down. Accordingly, when compared with an alternative case wherein key inputting operations are performed using only the single thumb as with a conventional portable telephone set, the efficiency in inputting operation is very high and a greater number of characters can be inputted per unit time. Further, while, where a conventional portable telephone set or a like apparatus is used, the operation burden is concentrated only upon a single particular finger such as the thumb and as a result the finger suffers from extremely great exhaustion or fatigue, with the portable information terminal according to the present invention, the burden of key inputting operations can be distributed to a plurality of fingers.

When, for example, two or more adjacent keys on the portable information terminal according to the present invention are depressed at a time using a single finger, the sense of touch provided by the projection on a key top and obtained from a fingertip is varied in response to the positional relationship between adjacent keys as described hereinabove with reference to FIGS. 7 to 15, 16 to 18, 19 to 21 and 22 to 24. Accordingly, before a key or keys are depressed, the location of the key or keys to be operated can be searched out precisely based on the sense of touch. Further, since the position of each key can be grasped without observing the keyboard face, blind touch operation can be realized readily.

Further, even when two keys are operated at a time, they can be depressed with comparatively light force as described hereinabove with reference to FIG. 4. Consequently, the burden to a fingertip is reduced.

Further, as described hereinabove with reference to FIGS. 5 and 6, with the portable information apparatus according to the present invention, a fingertip is acted upon by reactive forces in two perpendicular directions from the rib-like projection on the top face of each key 15. Accordingly, even if some finger is released, for example, in order to depress a different key or button, the portable information terminal is prevented from being let off due to reactive forces applied to the other fingertips. Further, even if two or more fingers of a hand with which the body of the portable information terminal is held are used to operate the keys or buttons, the portable information terminal is not let off from the palm.

Furthermore, since the single portable information terminal can have a “right hand mode” which provides an agreeable inputting environment (key assignment and so forth) when it is operated with the right hand, and a “left hand mode” which provides an agreeable inputting environment when it is operated with the left hand as described hereinabove with reference to FIGS. 2 and 3, it is not necessary to design, manufacture and ship two kinds of products and display them on the shop-front. Further, since the keys disposed on one side face of the body of the terminal 10 are commonly used by the fingers from the forefinger to the little finger of the left hand and the fingers from the forefinger to the little finger of the right hand, the number of inputting keys can be reduced to reduce the cost. Further, a key or button for operation with the thumb can be disposed on a side face of the body opposing to the inputting key set, that is, the keyboard as seen in FIG. 1. Further, as can be recognized from comparison between FIGS. 2 and 3, with whichever one of the right and left hands the portable information terminal 10 is grasped, the upward and downward directions of the display screen 12 are not reversed. Accordingly, if the body of the portable information terminal 10 is held with one hand until the hand becomes exhausted, then it can be passed from the hand to the other hand.

Further, where a direction inputting function is allocated for the button to be operated with the thumb as described hereinabove with reference to FIGS. 1 to 3, the mouse cursor can be operated on the display screen. In such an instance, keyboard inputting operation using the four fingers from the forefinger on down and coordinate and direction inputting operation using the thumb can be changed over freely.

Furthermore, though not shown, where the sizes of the key tops are varied such that the operation object area of the little finger may be smaller, the burden to the little finger whose muscular strength is comparatively low can be reduced.

While preferred embodiments of the present invention have been described using specific terms, such description is for illustrative purposes only, and it is to be understood that changes and variations may be made without departing from the spirit or scope of the following claims.

We claim as our invention

1. A portable information terminal which allows an inputting operation with one hand, comprising:
a polyhedral structure having a plurality of component faces including at least a first component face and a second component face, wherein the second component face is adjacent the first component face and may accept a plurality of different user inputs; and
a display screen accommodated on the first component face.

2. A portable information terminal as claimed in claim 1, further comprising:
at least four input keys arranged in a zigzag pattern on the second component face.

3. A portable information terminal as claimed in claim 1, further comprising:
at least four input keys arranged in a zigzag pattern on the second component face, each of the at least four input keys having a rib-like projection formed along a peripheral edge of a top face thereof.

4. A portable information terminal as claimed in claim 1, further comprising:
at least four input keys arranged in a zigzag pattern on the second component face, each of the at least four input keys having a projection formed at a substantially middle portion of a top face thereof.

5. A portable information terminal as claimed in claim 1, further comprising:
at least four input keys arranged in a zigzag pattern on the second component face, each of the at least four input keys having a projection formed at a substantially middle portion of a top face thereof, wherein the projections of adjacent input keys are continuous to each other.

6. A portable information terminal as claimed in claim 1, wherein the polyhedral structure includes a third component face as part of the plurality of component faces with which a thumb of a hand can contact such that the polyhedral structure can be supported by a portion of the hand proximate to a root of the thumb, and wherein the portable information terminal farther comprises at least four input keys arranged in a zigzag pattern on the second component face which can be operated with four fingers of the hand from a forefinger of the hand on down.

7. A portable information terminal as claimed in claim 1, wherein the polyhedral structure includes a third component face as part of the plurality of component faces disposed in an opposing position with respect to the second component face, the third component face including at least one of a key and a button disposed thereon for operation using a thumb of a hand, and wherein the portable information terminal further comprises at least four input keys arranged in a zigzag pattern on the second component face which can be operated with four fingers of the hand from a forefinger of the hand on down.

8. A portable information terminal as claimed in claim 1, wherein the polyhedral structure includes a third component face as part of the plurality of component faces, the third component face disposed in an opposing position with respect to the second component face, the third component face including at least one of a shift key, a control key, a caps lock key and an operation section for inputting one of a coordinate and a direction and which is operable using a thumb of a hand, and wherein the portable information terminal further comprises at least four input keys arranged in a zigzag pattern on the second component face which are operable with four fingers of the hand from a forefinger of the hand on down and to which at least one of alphanumeric characters and kana and kanji characters are allocated.

9. A portable information terminal as claimed in claim 1, wherein the polyhedral structure includes a third component face as part of the plurality of component faces disposed in an opposing position with respect to the second component face, the third component face including both a left hand operation section which can be operated using a thumb of a left hand and a right hand operation section which can be operated using a thumb of a right hand, and wherein the portable information terminal further comprises at least four input keys arranged in a zigzag pattern on the second component face which can be operated with four fingers of both the left hand and the right hand from a forefinger on down.

10. A portable information terminal as claimed in claim 1, wherein the portable information terminal is operable in both a left hand operation mode and a right hand operation mode, and wherein the portable information terminal further comprises a changeover port for changing over an allocation of input keys disposed on the second component face in response to a current operation mode of the portable information terminal.

11. A portable information terminal as claimed in claim 1, further comprising:
at least four input keys arranged in a zigzag pattern in two rows on the second component face wherein a key top of each of the at least four input keys in each of the two rows is supported for pivotal motion around a fulcrum at an edge portion thereof remote from the other key row such that a portion of each key top proximate to the other key row can be yieldably moved when depressed.

12. A portable information terminal as claimed in claim 1, further comprising:
at least four input keys arranged in a non-uniform key pitch in a zigzag pattern on the second component face.

13. A portable information terminal as claimed in claim 1, wherein at least one of a connection port to an external apparatus and a slot for insertion of a medium is disposed on one of the plurality of component faces other than the first and second component faces of the polyhedral structure.

14. A portable information terminal which allows an inputting operation with one hand, comprising:
a polyhedral structure having a plurality of component faces including at least a keyboard face and a thumb operation face, wherein the thumb operation face is disposed in an opposing position with respect to the keyboard face and may be contacted with a thumb of a hand; and
at least four input keys arranged in a zigzag pattern on the keyboard face, the at least four input keys being operable with four fingers of the hand from a forefinger of the hand on down.

15. A portable information terminal as claimed in claim 14, further comprising:
at least four rib-like projections, each of the at least four rib-like projections formed along a peripheral edge of a top face of a respective one of the at least four input keys.

16. A portable information terminal as claimed in claim 14, further comprising:
at least four projections, each of the at least four projections formed at a substantially middle portion of a top face of a respective one of the at least four input keys.

17. A portable information terminal as claimed in claim 14, further comprising:
at least four projections, each of the at least four projections formed at a substantially middle portion of a top face of a respective one of the at least four input keys such that the projections of adjacent input keys are continuous to each other.

18. A portable information terminal as claimed in claim 14, further comprising:
a left hand operation section arranged on the thumb operation face which can be operated using a thumb of a left hand; and
a right hand operation section arranged on the thumb operation face which can be operated using a thumb of a right hand.

19. A portable information terminal as claimed in claim 14, wherein the portable information terminal can operate in both a left hand operation mode and a right hand operation mode, and wherein the portable information terminal further comprises a changeover section for changing over allocation of the at least four input keys in response to a current operation mode of the portable information terminal.

20. A portable information terminal as claimed in claim 14, wherein the at least four input keys are further arranged in two rows on the keyboard face such that a key top of each of the at least four input keys in each of the two rows is supported for pivotal motion around a fulcrum at an edge portion of the key top remote from the other key row such that a portion of the key top proximate to the other key row can be yieldably moved when depressed.

21. A portable information terminal as claimed in claim 14, wherein the at least four input keys are arranged in a non-uniform key pitch.
